(19) United States
(12) Patent Application Publication
(10) Pub. No.: US 2024/0099073 A1
(43) Pub. Date: Mar. 21, 2024

(54) DISPLAY DEVICE AND MANUFACTURING METHOD THEREOF

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 18/470,445

(22) Filed: Sep. 20, 2023

(30) Foreign Application Priority Data
Sep. 21, 2022 (JP) 2022-150081

(51) Int. Cl. H10K 59/122; H10K 59/12; H10K 59/80

(52) U.S. Cl. CPC H10K 59/122; H10K 59/1201; H10K 59/873; H10K 59/879

(57) ABSTRACT

According to one embodiment, a display device includes an insulating layer formed of an inorganic material, a lower electrode provided on the insulating layer, a partition which surrounds the lower electrode and includes a conductive lower portion provided on the insulating layer and an upper portion protruding from a side surface of the lower portion, an organic layer which covers the lower electrode and emits light based on application of voltage, and an upper electrode which covers the organic layer and is in contact with the lower portion. The lower electrode includes an end portion located under the upper portion and having a thickness which decreases toward the lower portion.

### CROSS-REFERENCE TO RELATED APPLICATIONS

This application is based upon and claims the benefit of priority from Japanese Patent Application No. 2022-150081, filed Sep. 21, 2022, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

In the display devices described above, a technique which improves the luminous efficiency of the display element is required.

### BRIEF DESCRIPTION OF THE DRAWINGS

FIG. 1 is a diagram showing a configuration example of a display device according to an embodiment.

FIG. 2 is a diagram showing an example of the layout of subpixels.

FIG. 3 is a schematic cross-sectional view of the display device along the III-III line of FIG. 2.

FIG. 4 is a diagram showing an example of a layer structure which could be applied to an organic layer.

FIG. 5 is a schematic cross-sectional view in which a partition and its vicinity are enlarged.

FIG. 6 is a flowchart showing an example of the manufacturing method of the display device.

FIG. 7 is a schematic cross-sectional view showing the manufacturing process of the display device.

FIG. 8 is a schematic cross-sectional view showing a manufacturing process following FIG. 7.

FIG. 9 is a schematic cross-sectional view showing a manufacturing process following FIG. 8.

FIG. 10 is a schematic cross-sectional view showing a manufacturing process following FIG. 9.

FIG. 11 is a schematic cross-sectional view showing a manufacturing process following FIG. 10.

FIG. 12 is a schematic cross-sectional view showing a manufacturing process following FIG. 11.

FIG. 13 is a schematic cross-sectional view showing a manufacturing process following FIG. 12.

FIG. 14 is a schematic cross-sectional view showing a manufacturing process following FIG. 13.

FIG. 15 is a schematic cross-sectional view showing a manufacturing process following FIG. 14.

FIG. 16 is a schematic cross-sectional view showing a manufacturing process following FIG. 15.

FIG. 17 is a schematic cross-sectional view showing a manufacturing process following FIG. 16.

FIG. 18 is a schematic cross-sectional view showing a manufacturing process following FIG. 17.

### DETAILED DESCRIPTION

In general, according to one embodiment, a display device comprises an insulating layer formed of an inorganic material, a lower electrode provided on the insulating layer, a partition which surrounds the lower electrode and includes a conductive lower portion provided on the insulating layer and an upper portion protruding from a side surface of the lower portion, an organic layer which covers the lower electrode and emits light based on application of voltage, and an upper electrode which covers the organic layer and is in contact with the lower portion. The lower electrode comprises an end portion located under the upper portion and having a thickness which decreases toward the lower portion.

According to another aspect of the embodiment, a manufacturing method of a display device includes forming an insulating layer by an inorganic material, forming a partition which includes a conductive lower portion provided on the insulating layer and an upper portion protruding from a side surface of the lower portion, forming a lower electrode on the insulating layer and the partition by vapor deposition, forming an organic layer which emits light based on application of voltage on the lower electrode by vapor deposition, and forming an upper electrode which is in contact with the lower portion on the organic layer by vapor deposition.

These configurations can improve, for example, the luminous efficiency of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

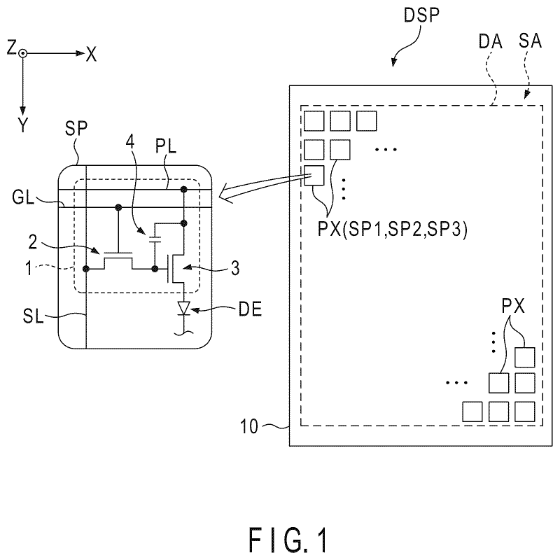

FIG. 1 is a diagram showing a configuration example of a display device DSP according to an embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. It should be noted that each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE. The display element DE is an organic light emitting diode (OLED) as a light emitting element.

It should be noted that the configuration of the pixel circuit 1 is not limited to the example shown in the figure. For example, the pixel circuit 1 may comprise more thin-film transistors and capacitors.

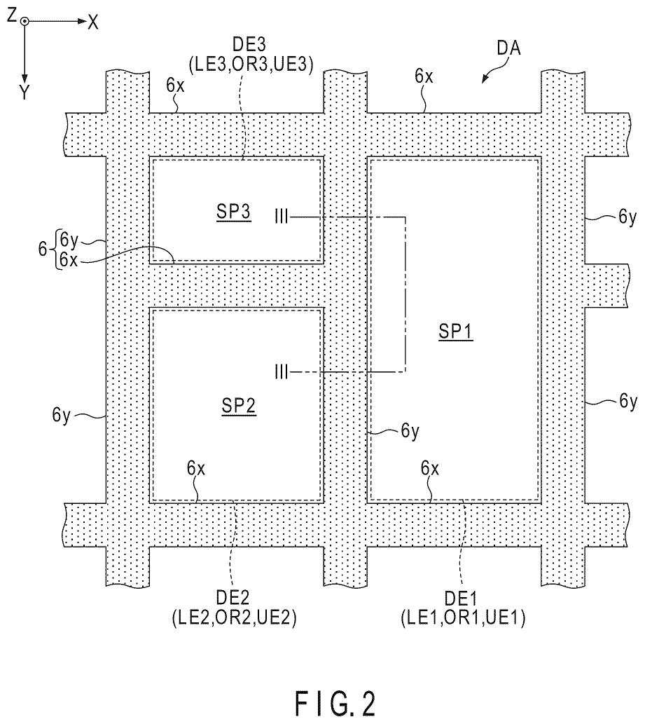

FIG. 2 is a diagram showing an example of the layout of subpixels SP1, SP2 and SP3. In the example of FIG. 2, subpixels SP1 and SP2 are arranged in the first direction X. Subpixels SP1 and SP3 are also arranged in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

Subpixel SP1 comprises a display element DE1. Subpixel SP2 comprises a display element DE2. Subpixel SP3 comprises a display element DE3. The display element DE1 includes a lower electrode LE1, an organic layer OR1 and an upper electrode UE1. The display element DE2 includes a lower electrode LE2, an organic layer OR2 and an upper electrode UE2. The display element DE3 includes a lower electrode LE3, an organic layer OR3 and an upper electrode UE3. The organic layers OR1, OR2 and OR3 emit light based on the application of voltage. Each of the display elements DE1, DE2 and DE3 may include a cap layer as described later.

In the example of FIG. 2, the area of the display element DE1 is greater than that of the display element DE2. The area of the display element DE1 is greater than that of the display element DE3. Further, the area of the display element DE3 is less than that of the display element DE2.

In the boundaries of subpixels SP1, SP2 and SP3, a partition 6 is provided. The partition 6 comprises a plurality of first partitions 6x extending in the first direction X and a plurality of second partitions 6y extending in the second direction Y. In the example of FIG. 2, the first partitions 6x and the second partitions 6y are connected to each other. In this structure, the partition 6 has a grating shape which surrounds the display elements DE1, DE2 and DE3 as a whole. In other words, the partition 6 comprises an aperture in each of subpixels SP1, SP2 and SP3.

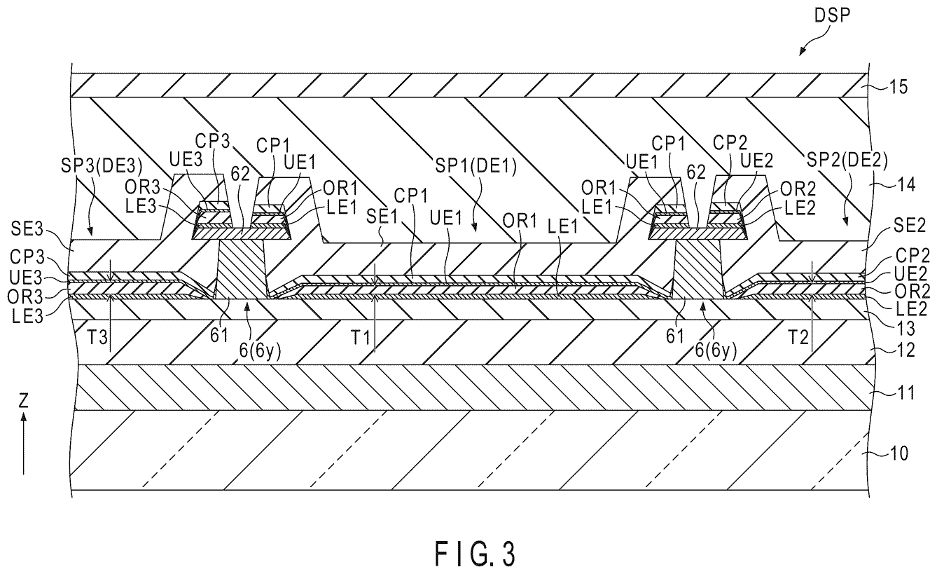

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an organic insulating layer 12. The organic insulating layer 12 is covered with an inorganic insulating layer 13. The organic insulating layer 12 functions as a planarization film which planarizes the irregularities formed by the circuit layer 11. The inorganic insulating layer 13 prevents moisture from entering the organic insulating layer 12 and the circuit layer 11 provided under the organic insulating layer 12.

The partition 6 includes a conductive lower portion 61 provided on the inorganic insulating layer 13 and an upper portion 62 provided on the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 is called an overhang shape.

The lower electrodes LE1, LE2 and LE3 are provided on the inorganic insulating layer 13 in a manner similar to that of the lower portion 61. The lower electrodes LE1, LE2 and LE3 are spaced apart from the lower portion 61. Although not shown in the section of FIG. 3, the lower electrodes LE1, LE2 and LE3 are connected to the pixel circuits 1 of subpixels SP1, SP2 and SP3, respectively, through contact holes provided in the organic insulating layer 12 and the inorganic insulating layer 13.

The organic layer OR1 covers the lower electrode LE1. The upper electrode UE1 covers the organic layer OR1. The organic layer OR2 covers the lower electrode LE2. The upper electrode UE2 covers the organic layer OR2. The organic layer OR3 covers the lower electrode LE3. The upper electrode UE3 covers the organic layer OR3. The upper electrodes UE1, UE2 and UE3 are in contact with the side surfaces of the lower portion 61.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

A sealing layer SE1 is provided in subpixel SP1. A sealing layer SE2 is provided in subpixel SP2. A sealing layer SE3 is provided in subpixel SP3. The sealing layer SE1 continuously covers the display element DE1 including the lower electrode LE1, the organic layer OR1, the upper electrode UE1 and the cap layer CP1 and the partition 6 around the display element DE1. The sealing layer SE2 continuously covers the display element DE2 including the lower electrode LE2, the organic layer OR2, the upper electrode UE2 and the cap layer CP2 and the partition 6 around the display element DE2. The sealing layer SE3 continuously covers the display element DE3 including the lower electrode LE3, the organic layer OR3, the upper electrode UE3 and the cap layer CP3 and the partition 6 around the display element DE3.

In the example of FIG. 3, the lower electrode LE1, the organic layer OR1, the upper electrode UE1 and the cap layer CP1 are partly located on the partition 6 around subpixel SP1. These portions are spaced apart from, of the lower electrode LE1, the organic layer OR1, the upper electrode UE1 and the cap layer CP1, the portions located on the inorganic insulating layer 13 (the portions constituting the display element DE1). Similarly, the lower electrode LE2, the organic layer OR2, the upper electrode UE2 and the cap layer CP2 are partly located on the partition 6 around subpixel SP2. These portions are spaced apart from, of the lower electrode LE2, the organic layer OR2, the upper electrode UE2 and the cap layer CP2, the portions located on the inorganic insulating layer 13 (the portions constituting the display element DE2). Further, the lower electrode LE3, the organic layer OR3, the upper electrode UE3 and the cap layer CP3 are partly located on the partition 6 around subpixel SP3. These portions are spaced apart from, of the lower electrode LE3, the organic layer OR3, the upper electrode UE3 and the cap layer CP3, the portions located on the inorganic insulating layer 13 (the portions constituting the display element DE3).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE1 and SE3 located above the partition 6 between subpixels SP1 and SP3 are spaced apart from each other.

The sealing layers SE1, SE2 and SE3 are covered with a resin layer 14. The resin layer 14 is covered with a sealing layer 15. A resin layer may be further provided on the sealing layer 15. The organic insulating layer 12 is formed of an organic material. Each of the inorganic insulating layer 13, the sealing layers SE1, SE2 and SE3 and the sealing layer 15 is formed of, for example, an inorganic material such as silicon nitride (SiNx). Each of the inorganic insulating layer 13, the sealing layers SE1, SE2 and SE3 and the sealing layer 15 may be formed of a single-layer body of one of silicon oxide (SiOx), silicon oxynitride (SiON) and aluminum oxide (Al₂O₃). Each of the inorganic insulating layer 13, the sealing layers SE1, SE2 and SE3 and the sealing layer 15 may be formed of a stacked layer body of a combination consisting of at least two of a silicon nitride layer, a silicon oxide layer, a silicon oxynitride layer and an aluminum oxide layer.

Each of the lower electrodes LE1, LE2 and LE3 comprises, for example, a single-layer structure of a metal material which has an excellent light reflectivity such as silver (Ag). The upper surfaces of these lower electrodes LE1, LE2 and LE3 are in contact with the organic layers OR1, OR2 and OR3, respectively. As another example, each of the lower electrodes LE1, LE2 and LE3 may include a reflective layer formed of a metal material such as silver and a conductive oxide layer provided between the reflective layer and the inorganic insulating layer 13. In this case, the adhesion between the lower electrodes LE1, LE2 and LE3 and the inorganic layer 13 is improved compared with a case where the reflective layer is in contact with the inorganic insulating layer 13. This conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the cap layers CP1, CP2 and CP3 is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that the cap layers CP1, CP2 and CP3 may be omitted.

The lower portion 61 of the partition 6 is formed of, for example, aluminum (Al). The lower portion 61 may be formed of an aluminum alloy such as an aluminum-neodymium alloy (AlNd) or may comprise a multilayer structure consisting of an aluminum layer and an aluminum alloy layer. Further, the lower portion 61 may comprise a thin film formed of a metal material different from aluminum and an aluminum alloy under the aluminum layer or the aluminum alloy layer. This thin film can be formed of, for example, molybdenum (Mo).

For example, the upper portion 62 of the partition 6 comprises a multilayer structure consisting of a thin film formed of a metal material such as titanium (Ti) and a thin film formed of conductive oxide such as ITO. The upper portion 62 may comprise a single-layer structure of a metal material such as titanium.

Common voltage is applied to the partition 6. This common voltage is applied to each of the upper electrodes UE1, UE2 and UE3 which are in contact with the side surfaces of the lower portion 61. Pixel voltage is applied to the lower electrodes LE1, LE2 and LE3 through the pixel circuits 1 provided in subpixels SP1, SP2 and SP3, respectively.

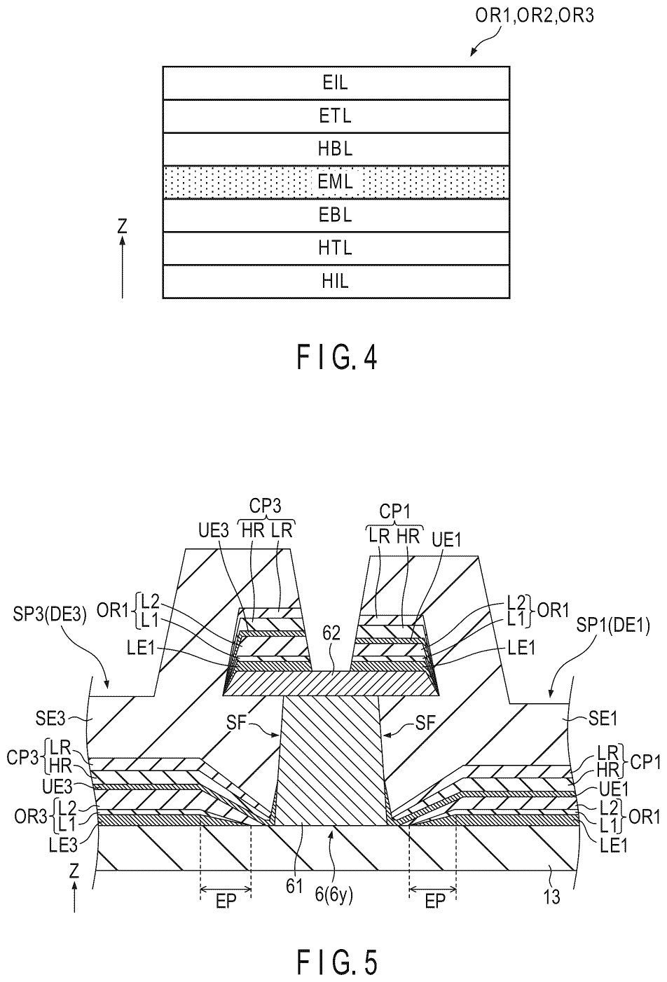

FIG. 4 is a diagram showing an example of a layer structure which could be applied to the organic layers OR1, OR2 and OR3. Each of the organic layers OR1, OR2 and OR3 comprises, for example, a structure in which a hole injection layer HIL, a hole transport layer HTL, an electron blocking layer EBL, a light emitting layer EML, a hole blocking layer HBL, an electron transport layer ETL and an electron injection layer EIL are stacked in order in a third direction Z. Each of the organic layers OR1, OR2 and OR3 may comprise a tandem structure including a plurality of light emitting layers EML.

When a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range.

To improve the light extraction efficiency of the display elements DE1, DE2 and DE3, the thicknesses of the organic layers OR1, OR2 and OR3 should be preferably adjusted based on the wavelengths of the light emitted from the light emitting layers EML. In the example of FIG. 3, thickness T1 of the organic layer OR1, thickness T2 of the organic layer OR2 and thickness T3 of the organic layer OR3 are different from each other. Specifically, thickness T2 is greater than thickness T1, and thickness T3 is greater than thickness T2 (T1<T2<T3). This difference in thicknesses T1, T2 and T3 is generated as, for example, the thicknesses of the hole transport layers HTL of the organic layers OR1, OR2 and OR3 are different from each other. However, the configuration is not limited to this example.

FIG. 5 is a schematic cross-sectional view in which the partition 6 between subpixels SP1 and SP3 and its vicinity are enlarged. The lower portion 61 comprises a pair of side surfaces SF. The upper portion 62 protrudes relative to these side surfaces SF in the width direction of the partition 6. It should be noted that the width direction of the partition 6 corresponds to the second direction Y regarding the first partition 6x shown in FIG. 2 and corresponds to the first direction X regarding the second partition 6y.

The lower electrode LE1 comprises an end portion EP in which the thickness decreases toward the side surface SF. At least part of the end portion EP is located under the upper portion 62. In other words, at least part of the end portion EP overlaps the upper portion 62 as seen in plan view. The end portion EP is spaced apart from the side surface SF.

The organic layer OR1 covers the entire lower electrode LE1 including the end portion EP. In the example of FIG. 5, the inorganic insulating layer 13 is exposed from the lower electrode LE1 between the end portion EP and the lower portion 61. The organic layer OR1 is in contact with this exposed portion.

The organic layer OR1 comprises a first layer L1 and a second layer L2 which covers the first layer L1. Of the layers shown in FIG. 4, at least the hole injection layer HIL is included in the first layer L1, and the layers which are not included in the first layer L1 are included in the second layer L2. For example, the first layer L1 consists of the hole injection layer HIL, and the second layer L2 consists of the hole transport layer HTL, the electron blocking layer EBL, the light emitting layer EML, the hole blocking layer HBL, the electron transport layer ETL and the electron injection layer EIL.

In the example of FIG. 5, neither the first layer L1 nor the second layer L2 is in contact with the lower portion 61. As another example, the second layer L2 may be in contact with the lower portion 61. It is preferable that the first layer L1 should not be in contact with the lower portion 61.

The upper electrode UE1 entirely covers the second layer L2 of the organic layer OR1. Further, the upper electrode UE1 is in contact with the side surface SF. In the example of FIG. 5, the upper electrode UE1 is in contact with, of the inorganic insulating layer 13, the portion exposed from the lower electrode LE1 and the organic layer OR1.

The cap layer CP1 includes a high-refractive layer HR which covers the upper electrode UE1, and a low-refractive layer LR which covers the high-refractive layer HR. The low-refractive layer LR has a refractive index less than that of the high-refractive layer HR. These high-refractive layer HR and low-refractive layer LR are examples of the transparent thin films constituting the multilayer body described above. The cap layer CP1 may include more thin films.

The thickness of the end portion of each of the organic layer OR1, the upper electrode UE1 and the cap layer CP1 decreases toward the side surface SF in a manner similar to that of the end portion EP of the lower electrode LE1. At least part of each of these end portions is located under the upper portion 62.

Of the side surface SF facing subpixel SP1, the area which is not covered with the upper electrode UE1 is covered with the sealing layer SE1. The sealing layer SE1 also continuously covers the lower surface of the upper portion 62 and the stacked layer body of the lower electrode LE1, organic layer OR1, upper electrode UE1 and cap layer CP1 provided on the upper portion 62.

The configuration of the lower electrode LE3, the organic layer OR3, the upper electrode UE3, the cap layer CP3 and the sealing layer SE3 shown in FIG. 5 is similar to that of the lower electrode LE1, the organic layer OR1, the upper electrode UE1, the cap layer CP1 and the sealing layer SE1. The configuration of the lower electrode LE2, the organic layer OR2, the upper electrode UE2, the cap layer CP2 and the sealing layer SE2 is also similar to that of the lower electrode LE1, the organic layer OR1, the upper electrode UE1, the cap layer CP1 and the sealing layer SE1.

Now, this specification explains the manufacturing method of the display device DSP.

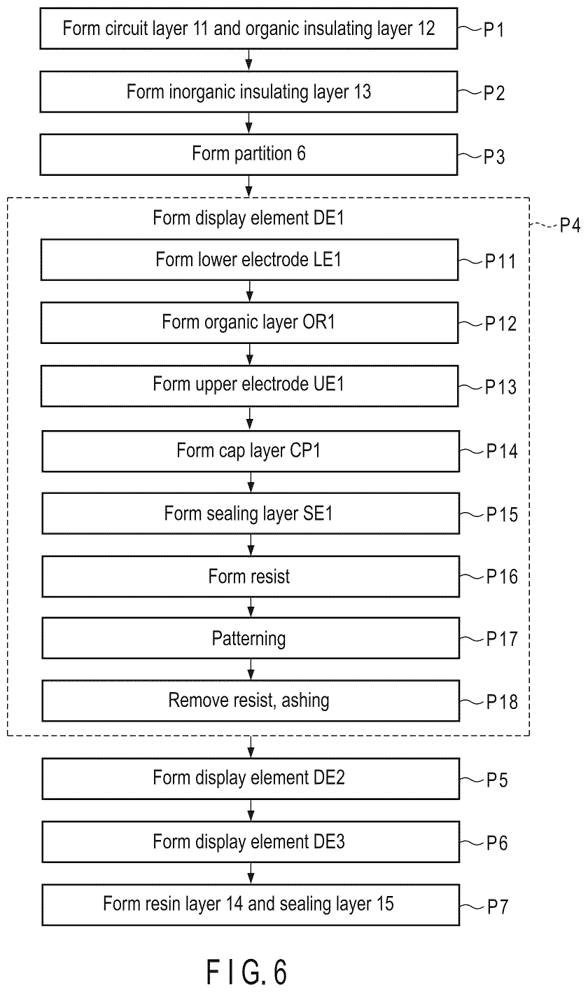

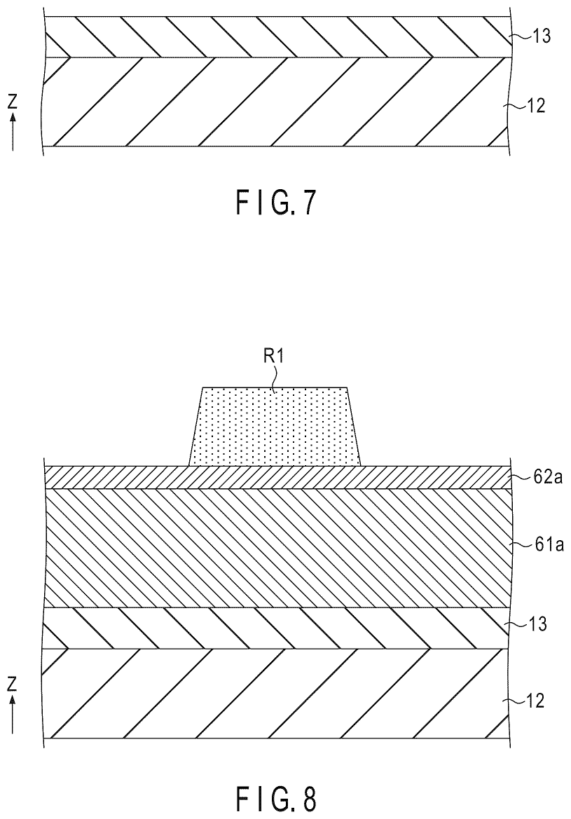

FIG. 6 is a flowchart showing an example of the manufacturing method of the display device DSP. Each of FIG. 7 to FIG. 18 is a schematic cross-sectional view showing part of the manufacturing process of the display device DSP. In FIG. 7 to FIG. 18, the substrate 10 and the circuit layer 11 are omitted.

To manufacture the display device DSP, first, the circuit layer 11 and the organic insulating layer 12 are formed on the substrate 10 (process P1). Further, as shown in FIG. 7, the inorganic insulating layer 13 is formed on the organic insulating layer 12 (process P2).

After process P2, the partition 6 is formed on the inorganic insulating layer 13 (process P3). Specifically, first, as shown in FIG. 8, a metal layer 61a which is the base of the lower portion 61 is formed on the inorganic insulating layer 13, and a thin film 62a which is the base of the upper portion 62 is formed on the metal layer 61a. Further, a resist R1 based on the shape of the partition 6 is formed on the thin film 62a.

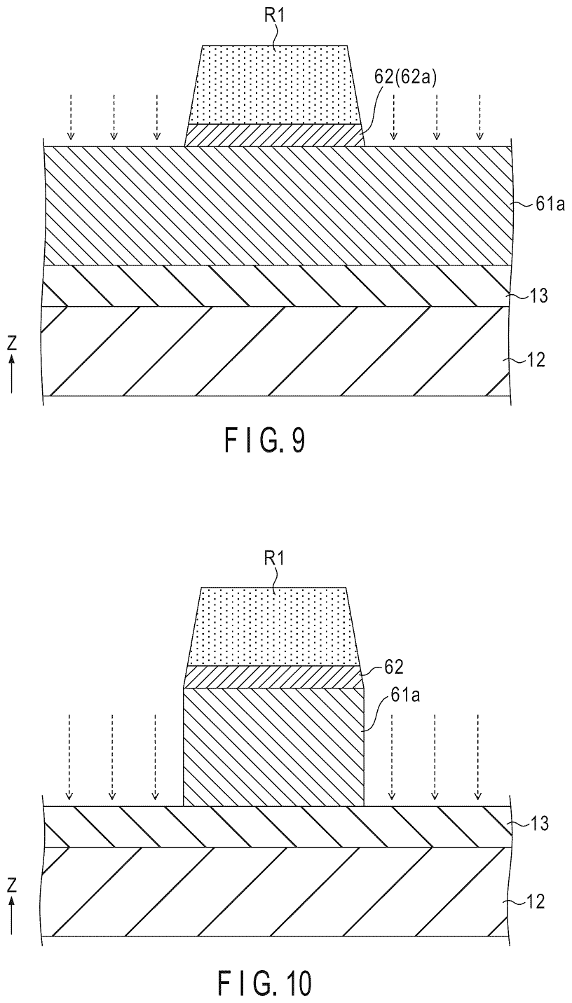

After the formation of the resist R1, as shown in FIG. 9, of the thin film 62a, the portion exposed from the resist R1 is removed by wet etching. By this process, the upper portion 62 is formed.

Subsequently, anisotropic dry etching is performed, and as shown in FIG. 10, of the metal layer 61a, the portion exposed from the resist R1 is removed. It should be noted that, of the metal layer 61a, the portion exposed from the resist R1 may be thinly left in the dry etching.

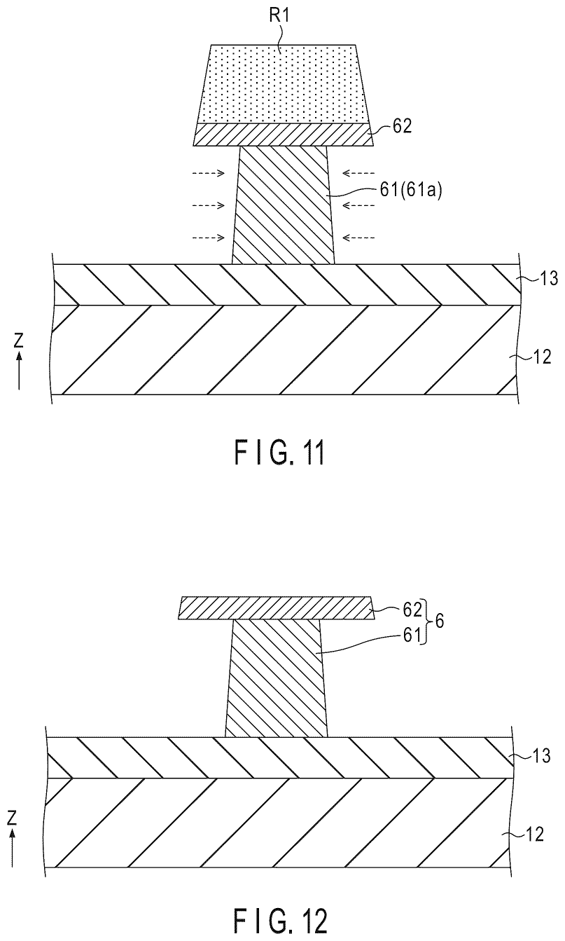

Subsequently, isotropic wet etching is applied. As shown in FIG. 11, the width of the metal layer 61a is reduced compared to that of the upper portion 62. By this process, the lower portion 61 having the shape shown in FIG. 5 is formed. After the formation of the lower portion 61, as shown in FIG. 12, the resist R1 is removed, and the partition 6 having an overhang shape is completed.

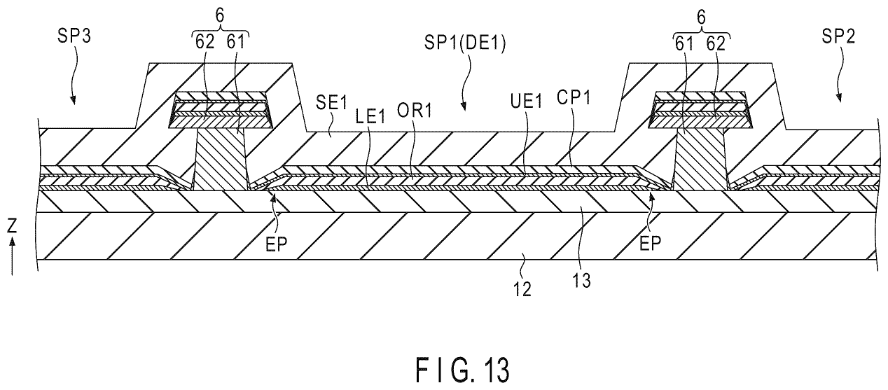

After process P3, the display element DE1 is formed (process P4). Specifically, as shown in FIG. 13, the lower electrode LE1 is formed on the inorganic insulating layer 13 and the partition 6 by vapor deposition (process P11). The organic layer OR1 is formed on the lower electrode LE1 by vapor deposition (process P12). The upper electrode UE1 is formed on the organic layer OR1 by vapor deposition (process P13). The cap layer CP1 is formed on the upper electrode UE1 by vapor deposition (process P14). Further, the sealing layer SE1 is formed by chemical vapor deposition (CVD) (process P15).

It should be noted that process P12 includes the process of forming the thin films constituting the organic layer OR1 in series, such as the hole injection layer HIL, hole transport layer HTL, electron blocking layer EBL, light emitting layer EML, hole blocking layer HBL, electron transport layer ETL and electron injection layer EIL shown in FIG. 4. Process P14 includes the process of forming the thin films constituting the cap layer CP1 in series, such as the high-refractive layer HR and low-refractive layer LR shown in FIG. 5.

The lower electrode LE1, the organic layer OR1, the upper electrode UE1, the cap layer CP1 and the sealing layer SE1 are formed in at least the entire display area DA and are provided in subpixels SP2 and SP3 as well as subpixel SP1. The lower electrode LE1, the organic layer OR1, the upper electrode UE1 and the cap layer CP1 are divided by the partition 6 having an overhang shape. The lower electrode LE1 is spaced apart from the lower portion 61. The upper electrode UE1 is in contact with the side surfaces of the lower portion 61. The sealing layer SE1 continuously covers the display element DE1 including the lower electrode LE1, the organic layer OR1, the upper electrode UE1 and the cap layer CP1 and the partition 6.

When the lower electrode LE1 is deposited, the evaporation material emitted from an evaporation source and proceeding to the vicinity of the base of the lower portion 61 is blocked by the upper portion 62. Thus, the thickness of the end portion EP of the lower electrode LE1 decreases toward the lower portion 61 as also shown in FIG. 5. This structure is also applied to the end portion of each of the organic layer OR1, the upper electrode UE1 and the cap layer CP1.

At least processes P11 and P12, preferably processes P11 to P15, are successively performed in a vacuum environment. In other words, at least from the start of process P11 until the completion of process P12, the circumference of the substrate which is the target of these processes is continuously maintained as a vacuum. Thus, the lower electrode LE1 formed in process P11 is covered with the lowest layer (for example, the hole injection layer HIL) of the organic layer OR1 in process P12 without exposure to the atmosphere.

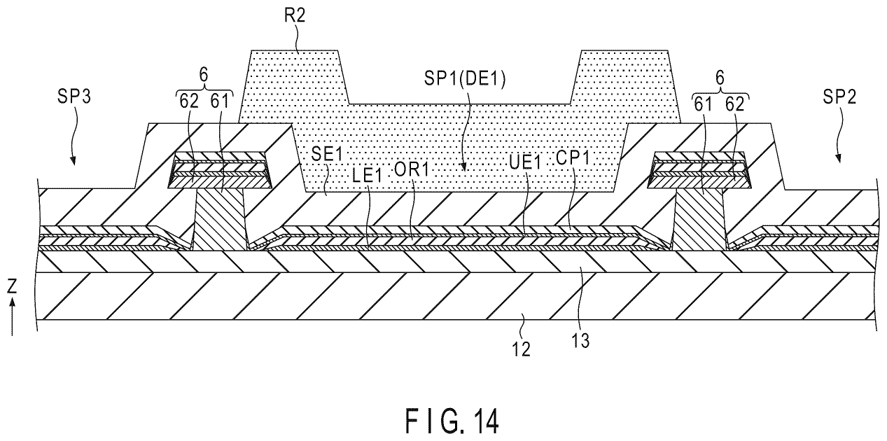

After process P15, as shown in FIG. 14, a resist R2 is provided on the sealing layer SE1 (process P16). The resist R2 covers subpixel SP1 and part of the partition 6 around the subpixel.

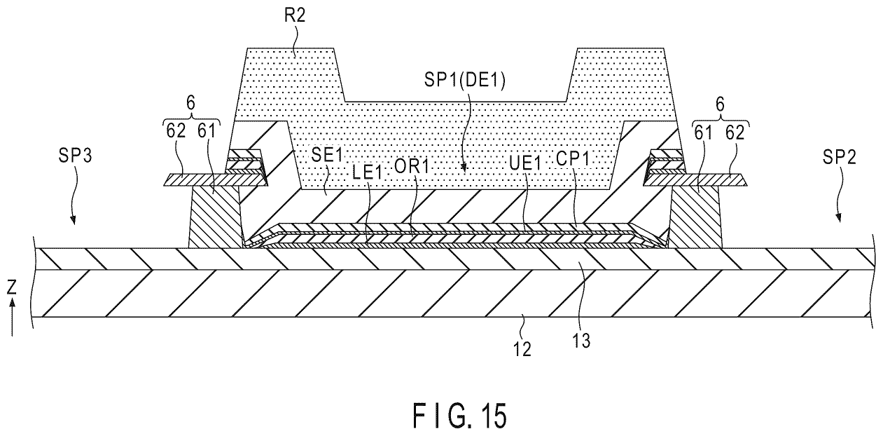

Subsequently, as shown in FIG. 15, the lower electrode LE1, the organic layer OR1, the upper electrode UE1, the cap layer CP1 and the sealing layer SE1 are patterned using the resist R2 as a mask (process P17). This process includes dry etching and wet etching for removing, of the lower electrode LE1, the organic layer OR1, the upper electrode UE1, the cap layer CP1 and the sealing layer SE1, the portions exposed from the resist R2 in series.

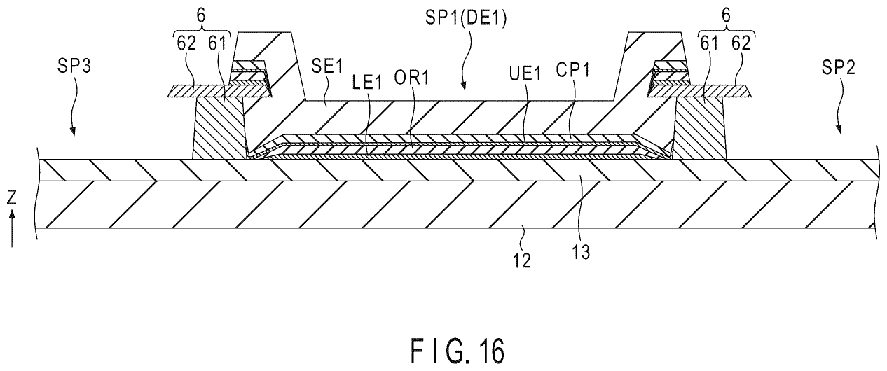

After process P17, the resist R2 is removed by an exfoliation liquid, and the residue of the resist R, etc., is removed by asking (process P18). This process allows the acquisition of the following substrate. As shown in FIG. 16, in the substrate, the display element DE1 and the sealing layer SE1 are formed in subpixel SP1, and neither a display element nor a sealing layer is formed in subpixel SP2 or subpixel SP3.

After the formation of the display element DE1, the display element DE2 is formed (process P5). The procedure of forming the display element DE2 is similar to processes P11 to P18. In other words, in a manner similar to that of processes P11 to P15, the lower electrode LE2, the organic layer OR2, the upper electrode UE2 and the cap layer CP2 are formed in order by vapor deposition, and the sealing layer SE2 is formed by CVD. As at least the lower electrode LE2 and the organic layer OR2 are successively formed in a vacuum environment, the lower electrode LE2 is covered with the organic layer OR2 without exposure to the atmosphere.

Subsequently, a resist is provided on the sealing layer SE2 in a manner similar to that of process P16. The lower electrode LE2, the organic layer OR2, the upper electrode UE2, the cap layer CP2 and the sealing layer SE2 are patterned in a manner similar to that of process P17. After this patterning, the resist is removed in a manner similar to that of process P18.

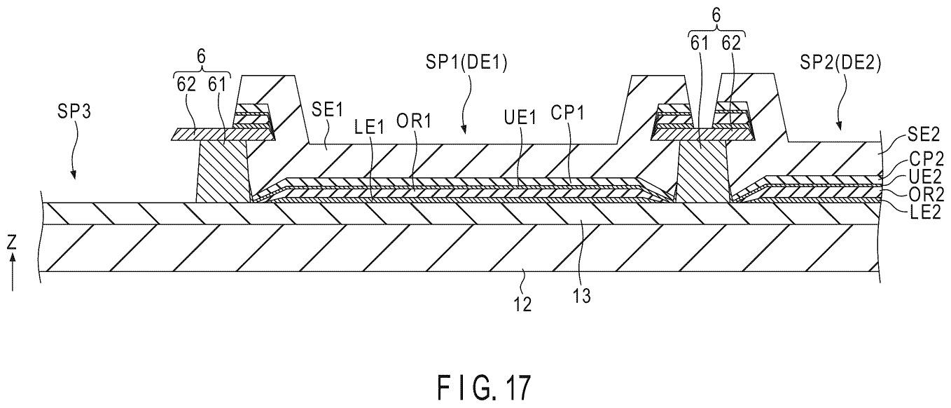

The above process allows the acquisition of the following substrate. As shown in FIG. 17, in the substrate, the display element DE1 and the sealing layer SE1 are formed in subpixel SP1, and the display element DE2 and the sealing layer SE2 are formed in subpixel SP2, and neither a display element nor a sealing layer is formed in subpixel SP3.

After the formation of the display element DE2, the display element DE3 is formed (process P6). The procedure of forming the display element DE3 is similar to processes P11 to P18. In other words, in a manner similar to that of processes P11 to P15, the lower electrode LE3, the organic layer OR3, the upper electrode UE3 and the cap layer CP3 are formed in order by vapor deposition, and the sealing layer SE3 is formed by CVD. As at least the lower electrode LE3 and the organic layer OR3 are successively formed in a vacuum environment, the lower electrode LE3 is covered with the organic layer OR3 without exposure to the atmosphere.

Subsequently, a resist is provided on the sealing layer SE3 in a manner similar to that of process P16. The lower electrode LE3, the organic layer OR3, the upper electrode UE3, the cap layer CP3 and the sealing layer SE3 are patterned in a manner similar to that of process P17. After this patterning, the resist is removed in a manner similar to that of process P18.

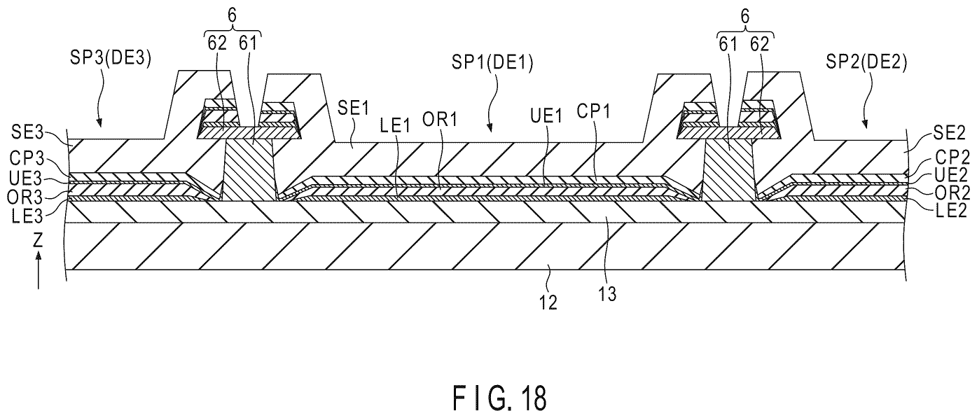

The above process allows the acquisition of the following substrate. As shown in FIG. 18, in the substrate, the display element DE1 and the sealing layer SE1 are formed in subpixel SP1, and the display element DE2 and the sealing layer SE2 are formed in subpixel SP2, and the display element DE3 and the sealing layer SE3 are formed in subpixel SP3.

After process P6, the resin layer 14 and sealing layer 15 shown in FIG. 3 are formed in order (process P7). By this process, the display device DSP is completed. In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

In conventional organic electroluminescent display devices, a lower electrode is patterned by a photolithographic process before the formation of an organic layer and an upper electrode. For example, when the lower electrode comprises a single-layer structure of silver, the surface of silver is exposed to an acid or alkaline chemical and the atmosphere in the process of patterning the lower electrode and various types of subsequent processes. Thus, the surface could be metamorphosed by sulfuration or oxidation, and the reflectance could be reduced. When the lower electrode comprises a single-layer structure of silver, a sufficient adhesion cannot be ensured relative to an insulating layer which is the base of the lower electrode. Thus, there is a possibility that the lower electrode is removed. To solve this problem, in general, a structure in which the lower and upper surfaces of a reflective layer formed of silver are covered with ITO is used for the lower electrode. In this structure, the deterioration of the upper surface of the reflective layer is prevented by the upper ITO layer, and the adhesion between the reflective layer and the base is improved by the lower ITO layer. The upper ITO layer has a thickness of, for example, approximately 5 to 10 nm.

The light emitted from the organic layer repeats reflection on the reflective layer and the interfaces of the layers provided above the reflective layer and is emitted from the display element. When the upper surface of the reflective layer is covered with an ITO layer, light is partially absorbed by the ITO layer in the process of the multiple reflections. In particular, regarding light in a blue wavelength range, the loss is large as the absorption index by the ITO layer is high. In a case where dry etching or wet etching using an acid chemical is performed after the formation of the lower electrode, the upper ITO layer needs to be thick so as to have a thickness of, for example, approximately 20 to 30 nm, and thus, the loss caused by light absorption is further increased.

In the manufacturing method of the display device DSP of the present embodiment, the lower electrode LE1 and the organic layer OR1 are successively deposited in a vacuum environment. This configuration is also applied to the lower electrode LE2 and the organic layer OR2, and the lower electrode LE3 and the organic layer OR3. In this case, the surface of the lower electrode LE1, LE2 or LE3 is not exposed to the atmosphere or a chemical. Thus, there is no need to cover the upper surface of the lower electrode LE1, LE2 or LE3 formed of a metal material such as silver with an ITO layer. By omitting this ITO layer, the absorption of the light emitted from the organic layers OR1, OR2 and OR3 is prevented. Further, as the deterioration of the upper surfaces of the lower electrodes LE1, LE2 and LE3 is prevented, a good hole injection property can be assured. By these configurations, the luminous efficiency of the display elements DE1, DE2 and DE3 is improved.

In addition, immediately after the lower electrodes LE1, LE2 and LE3 are formed, the organic layers OR1, OR2 and OR3, etc., are formed on the lower electrodes LE1, LE2 and LE3. Thus, even if the lower ITO layer is not provided, the removal of the lower electrodes LE1, LE2 and LE3 is prevented.

In the present embodiment, the partition 6 having an overhang shape is provided in the boundaries of subpixels SP1, SP2 and SP3. In this case, the lower electrodes LE1, LE2 and LE3, the organic layers OR1, OR2 and OR3, the upper electrodes UE1, UE2 and UE3, etc., formed by vapor deposition are divided by the partition 6. By covering these divided layers with the sealing layers SE1, SE2 and SE3, the display elements DE1, DE2 and DE3 which are individually sealed can be obtained. In a case where the display elements DE1, DE2 and DE3 are individually sealed, even if a problem such as moisture penetration occurs in one of the display elements, the spread of the effect to the other display elements is prevented.

The partition 6 functions as a line which supplies electricity to the upper electrodes UE1, UE2 and UE3. Thus, the lower electrodes LE1, LE2 and LE3 need to be spaced apart from the partition 6. In this respect, in the present embodiment, the upper portion 62 of the partition 6 protrudes relative to the side surfaces of the lower portion 61. In this case, the end portion EP of each of the lower electrodes LE1, LE2 and LE3 formed by vapor deposition has a shape in which the thickness decreases toward the lower portion 61 as described above. By this configuration, the contact between the lower electrodes LE1, LE2 and LE3 and the lower portion 61 can be further assuredly prevented.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
an insulating layer formed of an inorganic material;
a lower electrode provided on the insulating layer;
a partition which surrounds the lower electrode and includes a conductive lower portion provided on the insulating layer and an upper portion protruding from a side surface of the lower portion;
an organic layer which covers the lower electrode and emits light based on application of voltage; and
an upper electrode which covers the organic layer and is in contact with the lower portion, wherein
the lower electrode comprises an end portion located under the upper portion and having a thickness which decreases toward the lower portion.

2. The display device of claim 1, wherein
the lower electrode is formed of silver, and
the organic layer is in contact with an upper surface of the lower electrode.

3. The display device of claim 1, wherein
the lower electrode is partly located on the upper portion.

4. The display device of claim 1, wherein
the organic layer is in contact with the insulating layer between the end portion of the lower electrode and the lower portion.

5. The display device of claim 1, further comprising a sealing layer which continuously covers the partition and a display element including the lower electrode, the organic layer and the upper electrode.

6. The display device of claim 5, further comprising an optical adjustment layer located between the upper electrode and the sealing layer and having a refractive index different from refractive indices of the upper electrode and the sealing layer.

7. The display device of claim 1, wherein
the organic layer covers the entire lower electrode including the end portion.

8. The display device of claim 1, wherein
an end portion of the organic layer is spaced apart from the lower portion, and
the upper electrode is in contact with the insulating layer between the end portion of the organic layer and the lower portion.

9. A manufacturing method of a display device, including:
forming an insulating layer by an inorganic material;
forming a partition which includes a conductive lower portion provided on the insulating layer and an upper portion protruding from a side surface of the lower portion;
forming a lower electrode on the insulating layer and the partition by vapor deposition;
forming an organic layer which emits light based on application of voltage on the lower electrode by vapor deposition; and
forming an upper electrode which is in contact with the lower portion on the organic layer by vapor deposition.

10. The manufacturing method of claim 9, wherein
the lower electrode and the organic layer are successively formed in a vacuum environment.

11. The manufacturing method of claim 9, further including
forming a sealing layer which continuously covers the partition and a display element including the lower electrode, the organic layer and the upper electrode.

12. The manufacturing method of claim 11, wherein
the lower electrode, the organic layer, the upper electrode and the sealing layer are successively formed in a vacuum environment.

13. The manufacturing method of claim 11, further including
forming an optical adjustment layer which covers the upper electrode and has a refractive index different from refractive indices of the upper electrode and the sealing layer before forming the sealing layer.

14. The manufacturing method of claim 13, wherein
the lower electrode, the organic layer, the upper electrode and the optical adjustment layer are successively formed in a vacuum environment.

15. The manufacturing method of claim 13, further including:
providing a resist on the sealing layer; and
performing etching for removing portions of the lower electrode, the organic layer, the upper electrode, the optical adjustment layer and the sealing layer exposed from the resist.
